(19) United States
(12) Patent Application Publication
(10) Pub. No.: US 2025/0372447 A1
(43) Pub. Date: Dec. 4, 2025

(54) SEMICONDUCTOR DEVICES WITH AIR GAP AND MULTIPLE IMPLANT STEPS FOR SEALING THE AIR GAP

(71) Applicant: TAIWAN SEMICONDUCTOR MANUFACTURING COMPANY, LTD., Hsinchu (TW)

(72) Inventors: Kuo-Ju CHEN, Taichung (TW); Te-Jui YEN, Hsinchu (TW); Liang-Yin CHEN, Hsinchu (TW); Chien-Hao CHEN, Ilan (TW)

(21) Appl. No.: 18/680,158

(22) Filed: May 31, 2024

(51) Int. Cl. H01L 21/768; H01L 21/265; H01L 21/8234; H01L 23/522; H01L 27/088; H01L 29/06; H01L 29/08; H01L 29/423; H01L 29/66; H01L 29/775; H01L 29/786

(52) U.S. Cl. CPC H01L 21/7682; H01L 21/26586; H01L 23/5222; H10D 30/014; H10D 30/43; H10D 30/6735; H10D 30/6757; H10D 62/115; H10D 62/121; H10D 62/151; H10D 64/021; H10D 84/0128; H10D 84/013; H10D 84/038; H10D 84/83

(57) ABSTRACT

Embodiments of the present disclosure provide a semiconductor device comprising a pair of channel regions and a source/drain (S/D) region formed between the channel regions in a substrate, a metal gate on each of the channel regions and an interlayer dielectric layer (ILD) over the metal gates. An S/D metal contact is formed on the S/D region and extends between the pair of metal gates. The S/D metal contact is spaced from the metal gates and the ILD by an air gap structure. The air gap structure includes a sealed portion extending from a top surface to a bottom surface level of the first ILD and an unsealed portion extending from the bottom surface of the ILD to a top surface level of the S/D region.

### BACKGROUND

An integrated circuit (IC) typically includes a plurality of semiconductor devices, such as field-effect transistors and metal interconnection layers formed on a semiconductor substrate. The interconnection layers, designed to connect the semiconductor devices to power supplies, input/output signals, and to each other, may include signal lines and power rails. The semiconductor industry has experienced continuous rapid growth due to constant improvements in the performance of various electronic components, including the metal contacts and interconnection layers. For the most part, it is desirable to have lower capacitance and lower resistance in interconnection layers. However, interconnection features may have higher than desirable capacitance and/or resistance as a result of current technology used for forming the interconnection features. Therefore, there is a need to solve the above problems.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7, 8, 8A, 9, 9A, 10-12, 13, 13A, 16-18,19 and 19A schematically illustrate various stages of manufacturing a semiconductor device according to some embodiments of the present disclosure.

FIG. 20 is a flow chart of various operations of a method according to the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In current technologies, interconnect structures such as vias and conductive lines are formed over electronic components to provide connections between the electronic components such as transistors, capacitors, or the like, formed on the substrate, and to provide connections to external devices. To reduce parasitic capacitance C_{eff}, the interconnect structures may be formed in low-k dielectric material. However, even with the low-k dielectric, the parasitic capacitance may still exceed a tolerable range when the device dimensions continuously decrease in the advanced technology nodes. Therefore, air gaps formed between conductive structures have been developed to further reduce the capacitance.

While the embodiments of this disclosure are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure.

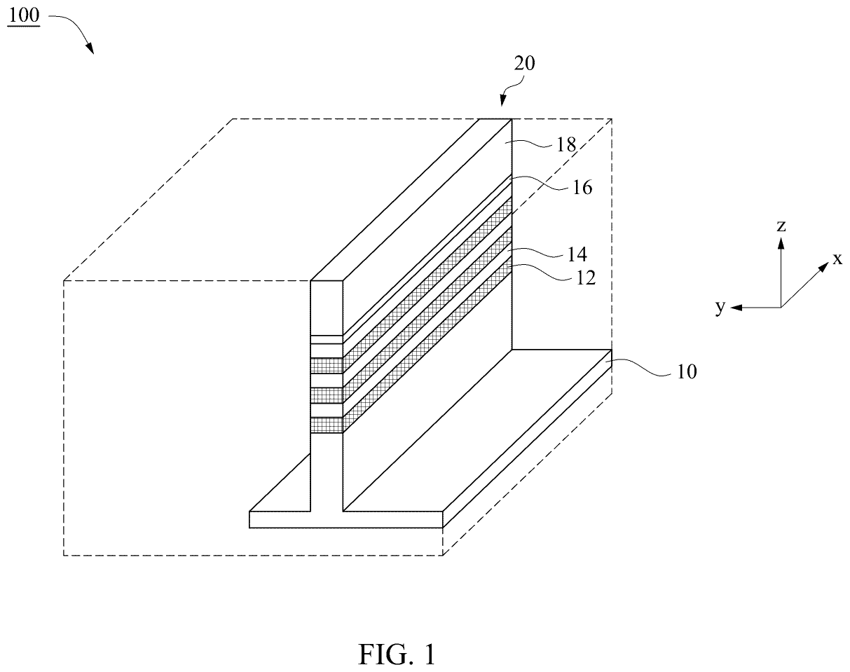

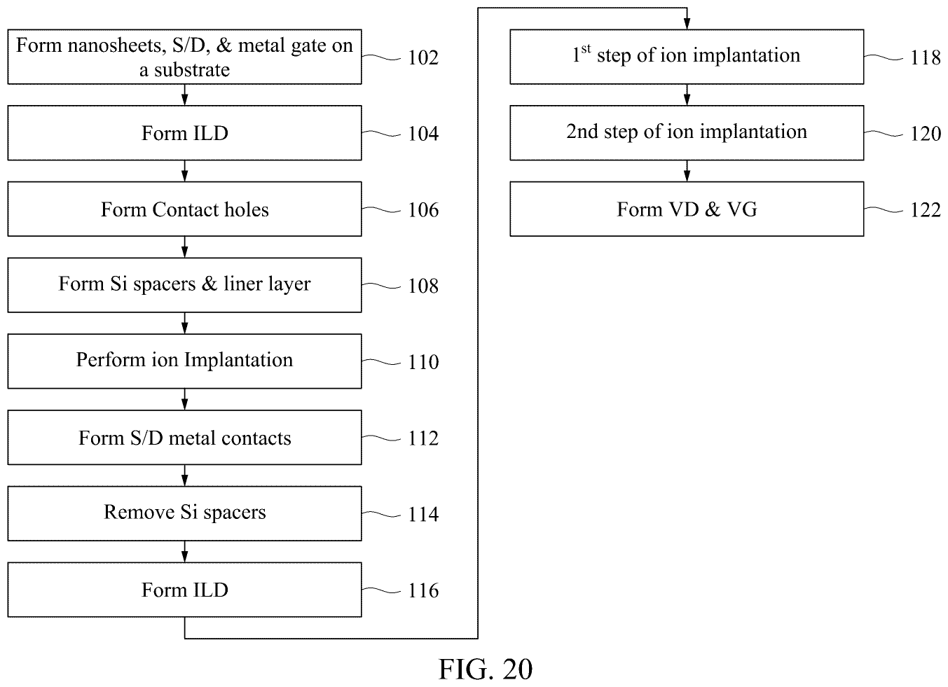

FIGS. 1 to 19 schematically illustrate various stages of manufacturing a semiconductor device structure 100 according to embodiments of the present disclosure. FIG. 20 is a flow chart of a method for manufacturing a semiconductor device structure according to embodiments of the present disclosure. Additional operations can be provided before, during, and after operations/processes in the method, and some of the operations described below can be replaced or eliminated, for additional embodiments of the method. The order of the operations/processes may be interchangeable.

As shown in FIG. 1, a fin structure 20 is formed over a semiconductor substrate 10. The substrate 10 is provided to form a semiconductor device thereon. The substrate 10 may include a single crystalline semiconductor material such as, but not limited to Si, Ge, SiGe, GaAs, InSb, GaP, GaSb, InAlAs, InGaAs, GaSbP, GaAsSb, and InP. The substrate 10 may include various doping configurations depending on circuit design. For example, different doping profiles, e.g., n-wells, p-wells, may be formed in the substrate 10 in regions designed for different device types, such as nFET and pFET. In some embodiments, the substrate 10 may be a silicon-on-insulator (SOI) substrate including an insulator structure (not shown) for enhancement.

To form the fin structure 20, one or more pairs of first semiconductor layer 12 and second semiconductor layer 14 are formed over the substrate 10. The semiconductor layers 12, 14 may be formed by a molecular beam epitaxy (MBE) process, a metalorganic chemical vapor deposition (MOCVD) process, and/or other suitable epitaxial growth processes. In some embodiments, the semiconductor layers 14 include the same material as the substrate 10. In some embodiments, the semiconductor layers 12 and 14 include different materials than the substrate 10. In some embodiments, the semiconductor layers 12 and 14 are made of materials having different lattice constants. The first semiconductor layers 12 in channel regions may eventually be removed and serve to define a vertical distance between adjacent channel regions for a subsequently formed multi-gate device. In some embodiments, the first semiconductor layers 12 include an epitaxially grown silicon germanium (SiGe) layer and the second semiconductor layers 14 include an epitaxially grown silicon (Si) layer. Alternatively, in some embodiments, either of the semiconductor layers 12 and 14 may include other materials such as Ge, a compound semiconductor such as SiC, GeAs, GaP, InP, InAs, and/or InSb, an alloy semiconductor such as SiGe, GaAsP, AllnAs, AlGaAs, InGaAs, GalnP, and/or GalnAsP, or combinations thereof.

The fin structure 20 is formed by patterning a pad layer 16 and a hard mask 18 formed on the pairs of semiconductor layers 12, 14, and then etching through the pairs of semiconductor layers 12, 14 and a portion of the substrate 10.

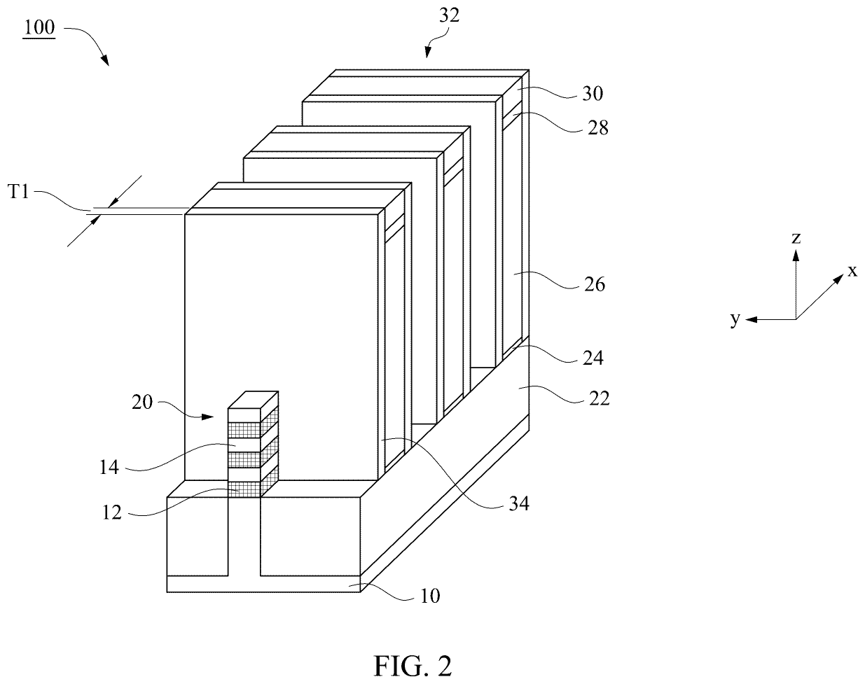

In FIG. 2, sacrificial gate structures 32 are formed over the fin structure 20, and sidewall spacers 34 are formed on sides of the sacrificial gate structure 32.

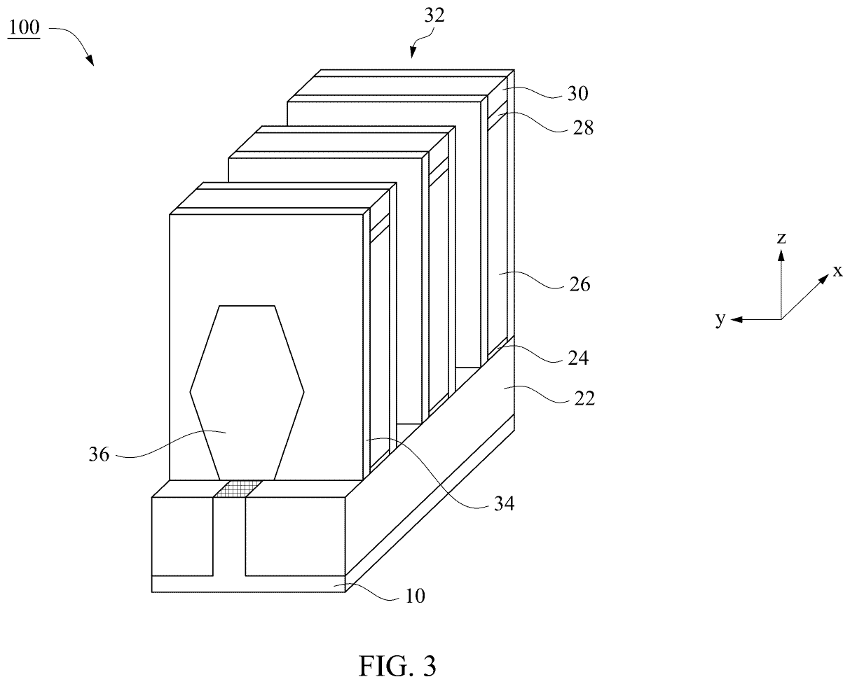

After formation of the fin structure 20, an isolation layer 22 is formed in trenches between the fin structures 20, as shown in FIG. 3. The isolation layer 22 is formed over the substrate 10 and then etched back to expose the pairs of semiconductor layers 12, 14. In some embodiments, the isolation layer 22 may include silicon oxide, silicon nitride, silicon oxynitride, fluorine-doped silicate glass (FSG), a low-k dielectric, combinations thereof.

The sacrificial gate structures 32 may include a sacrificial gate dielectric layer 24, a sacrificial gate electrode layer 26, a pad layer 28, and a mask layer 30. The sacrificial gate dielectric layer 24 may include one or more layers of dielectric material, such as SiO₂, SiN, a high-k dielectric material, and/or other suitable dielectric material. The sacrificial gate electrode layer 26 may include silicon such as polycrystalline silicon or amorphous silicon. The pad layer 28 may include silicon nitride. The mask layer 30 may include silicon oxide. Next, a patterning operation is performed on the mask layer 30, the pad layer 28, the sacrificial gate electrode layer 26 and the sacrificial gate dielectric layer 24 to form the sacrificial gate structure 32.

The sidewall spacers 34 are formed on sidewalls of each sacrificial gate structure 32. The sidewall spacers 34 may be formed from a dielectric material, such as SiO, SiN, SiC, SiCN, SiOC, SiON, SiOCN, or a combination thereof. In some embodiments, the insulating material of the sidewall spacers 34 is a silicon nitride-based material, such as SiN, SiON, SiOCN or SiCN and combinations thereof. In some embodiments, a thickness T1 of the sidewall spacer 34 is in a range between about 0.5 nm and about 10 nm.

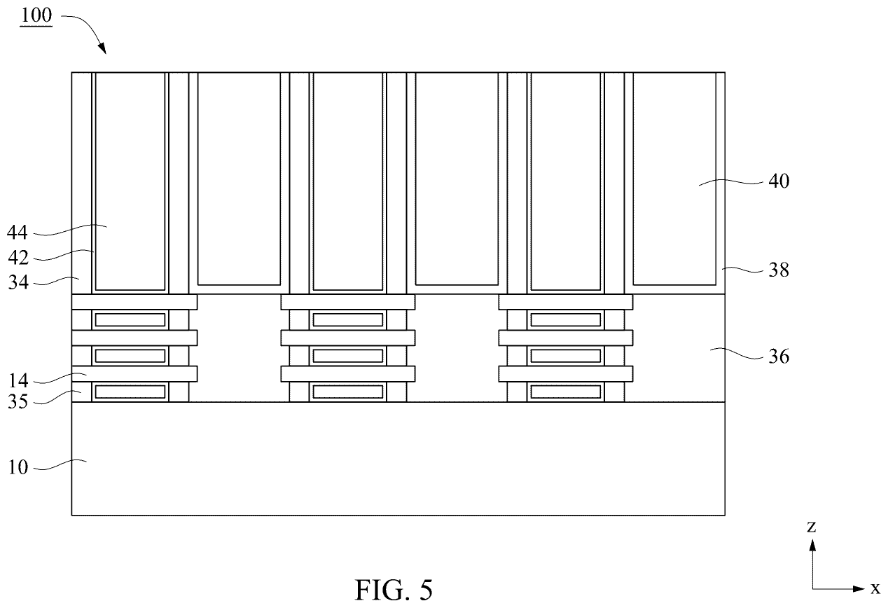

In FIG. 3, source/drain features 36 are formed on opposing sides of the sacrificial gate structures 32. The operation for forming the source/drain features 36 may include etching back portions of the fin structure 20 exposed outside the sacrificial gate structures 32, etching back the first semiconductor layers 12 from under the sidewall spacers 34 to form inner spacer cavities, forming inner spacers 35 (shown in FIG. 5) in the inner spacer cavities, and epitaxially growing the source/drain features 36 from the exposed surface of the substrate 10 and the second semiconductor layers 14.

The inner spacers 35 may be formed from a dielectric material, such as SiO, SiN, SiC, SiCN, SiOC, SiON, SiOCN, or a combination thereof. In some embodiments, the inner spacers 35 may include one of silicon nitride (SiN) and silicon oxide (SiO₂), SiONC, or a combination thereof.

The source/drain features 36 may include one or more semiconductor materials depending on the device type. The source/drain features 36 may be epitaxially grown material with a thickness in a range between about 0.5 nm to about 30 nm.

For n-type devices, the source/drain features 36 may include one or more layers of Si, SiP, SiC, SiCP, or a group III-V material (InP, GaAs, AlAs, InAs, InAIAs, InGaAs). In some embodiments, the source/drain features 36 may be doped with n-type dopants, such as phosphorus (P), arsenic (As), etc, for n-type devices.

For p-type devices, the source/drain features 36 may include one or more layers of Si, SiGe, SiGeB, Ge, or a group IlI-V material (InSb, GaSb, InGaSb). In some embodiments, the source/drain features 36 may be doped with p-type dopants, such as boron (B).

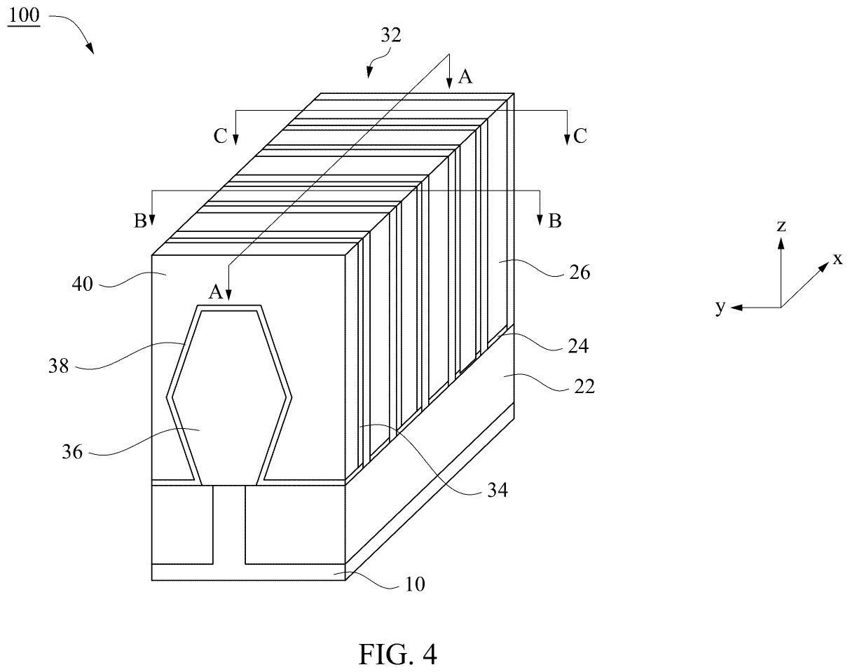

In FIG. 4, a contact etch stop layer (CESL) 38 and an interlayer dielectric (ILD) layer 40 are formed over the exposed surfaces. In the example, the CESL 38 is formed on the source/drain features 36, the sidewall spacers 34, and the isolation layer 22. The CESL 38 may include Si₃N₄, SiON, SiCN or any other suitable material, and may be formed by CVD, PVD, or ALD. In some embodiments, the CESL 38 may be formed from a material different from the sidewall spacers 34 so that the sidewall spacers 34 can be selectively etched back in the subsequent process to form SAC layers.

The interlayer dielectric (ILD) layer 40 is formed over the contact etch stop layer (CESL) 38. The materials for the ILD layer 40 include compounds comprising Si, O, C, and/or H, such as silicon oxide, SiCOH and SiOC. Organic materials, such as polymers, may be used for the ILD layer 40. The ILD layer 40 protects the source/drain features 36 during the removal of the sacrificial gate structures 32. A planarization operation, such as CMP, is performed to expose the sacrificial gate electrode layer 26 for subsequent removal of the sacrificial gate structures 32.

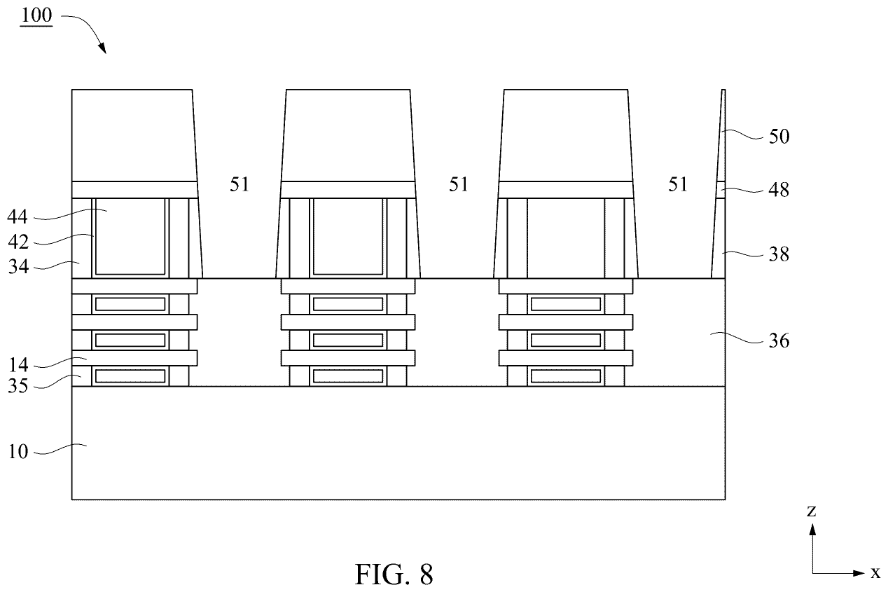

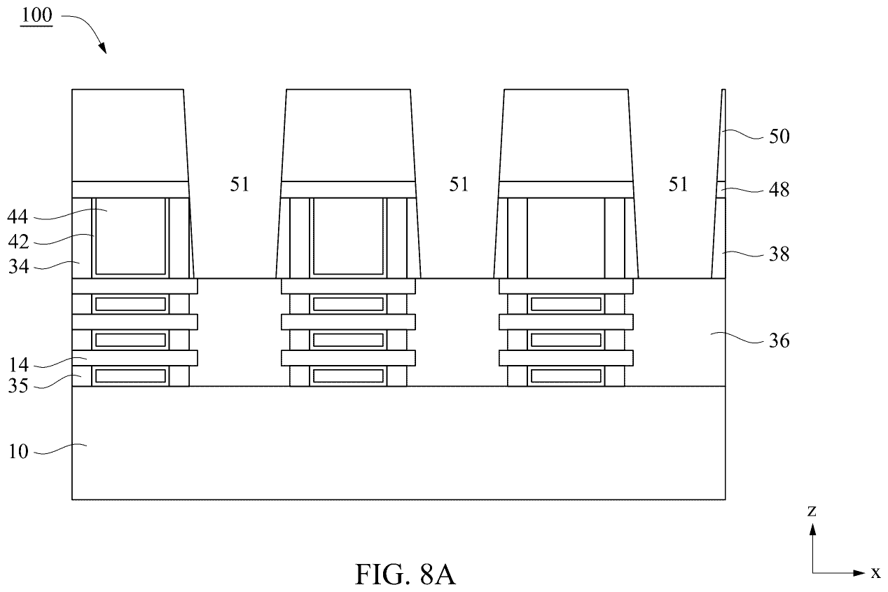

FIGS. 8, 8A, 9, 9A, 10-13, 13A, 14-19, and 19A are cross sectional views of the device along A-A line of FIG. 4 at various stages of fabrication according to the method as shown in FIG. 20.

A replacement gate sequence is performed to form a gate dielectric layer 42 and the gate electrode layer 44 as shown in FIG. 5. The replacement gate sequence may include removing the sacrificial gate electrode layer 26 and the sacrificial gate dielectric layer 24 to expose the fin structure 20 under the sacrificial gate structure 32. The first semiconductor layers 12 are subsequently removed resulting forming nanosheets of the second semiconductor layers 14.

The gate dielectric layer 42 is then deposited on exposed surfaces of each nanosheet of the second semiconductor layers 14, exposed surfaces of the inner spacers 35, and exposed surfaces of the sidewall spacers 34. The gate dielectric layer 42 may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. In some embodiments, the gate dielectric layer 42 has a dielectric constant about 7.

The gate electrode layer 44 is then formed over the gate dielectric layer 42. The gate electrode layer 44 includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. After the formation of the gate electrode layer 44, a planarization process, such as a CMP process, is performed to remove excess deposition of the gate electrode material and expose the top surface of the ILD layer 40.

As shown in FIG. 5, the one or more second semiconductor layers 14 connect the source/drain features 36 on opposing sides of the one or more second semiconductor layers 14 forming a multichannel transistor. The one or more semiconductor layers 14 function as a channel region between the source/drain features 36 of the multi-channel transistor. The connection between the source/drain features 36 may be controlled by the voltage applied to the gate electrode layer 44. Alternatively, the channel region may be a single channel transistor with a single channel fin-shape channel region or a planar channel region.

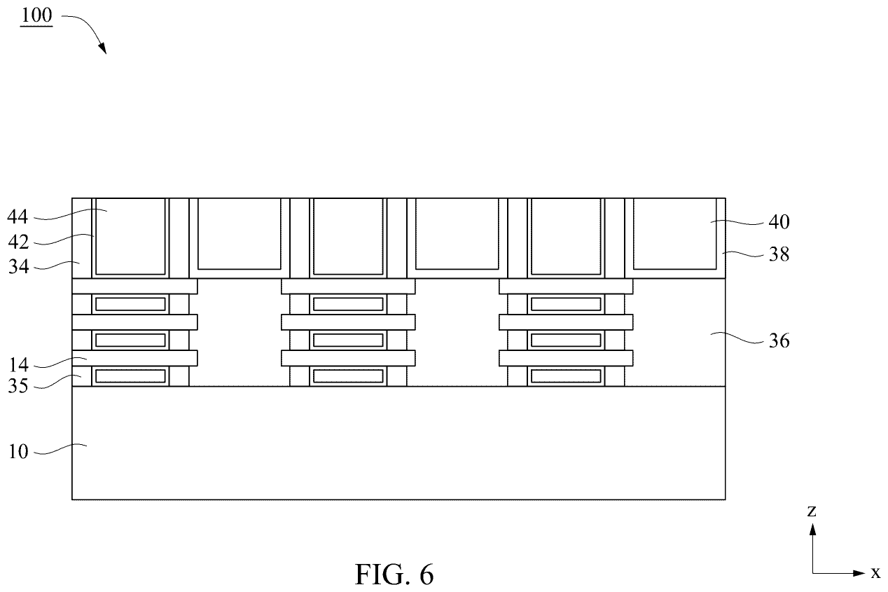

In FIG. 6, a chemical mechanical polishing (CMP) process is performed to remove portions of the gate dielectric layer 42, the gate electrode layer 44, the sidewall spacer 34, and the ILD layer 40, and the CESL 38.

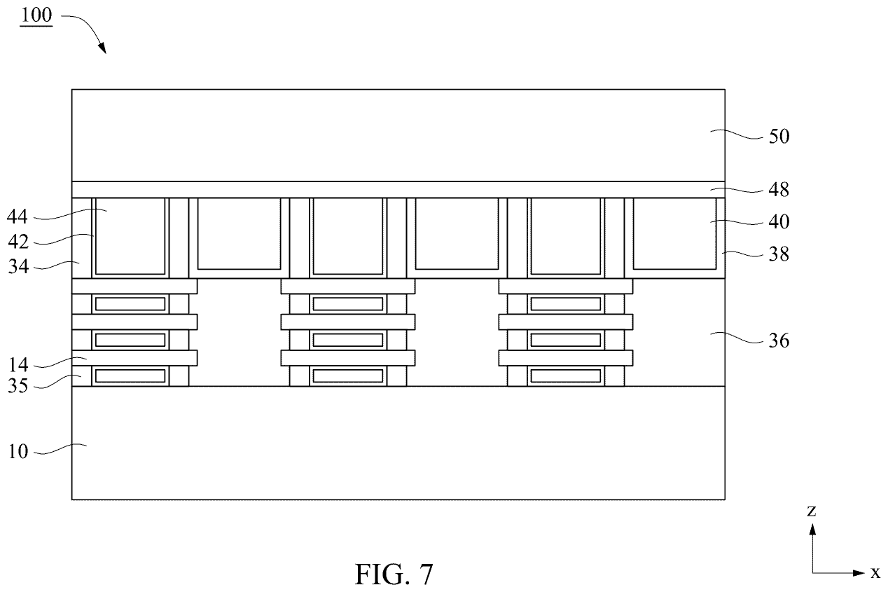

In FIG. 7, an inter-layer dielectric layer (ILD) 48 is formed over the gate structures (the remaining sidewall spacer 34, gate dielectric layer 42, and gate electrode layer 44) and the remaining CESL 38 and ILD 40. The ILD 48 may be formed by a suitable deposition process such as CVD, PVD, or ALD. The ILD 48 may be made with similar material to the CESL 38, including SiN or any other suitable materials.

Another ILD 50 is formed on the ILD 48. The ILD 50 may be any dielectric layer that can be used as an etch stop layer during subsequent trench and via patterning for metal contacts. In some embodiments, the ILD 50 may be a dielectric layer including but not limited to traethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), SiN, and/or other suitable dielectric materials. The ILD layer 50 may be formed by FCVD, PECVD, or other suitable methods. The ILD layer 50 may have a thickness ranging between about 0.5 nm and about 30 nm.

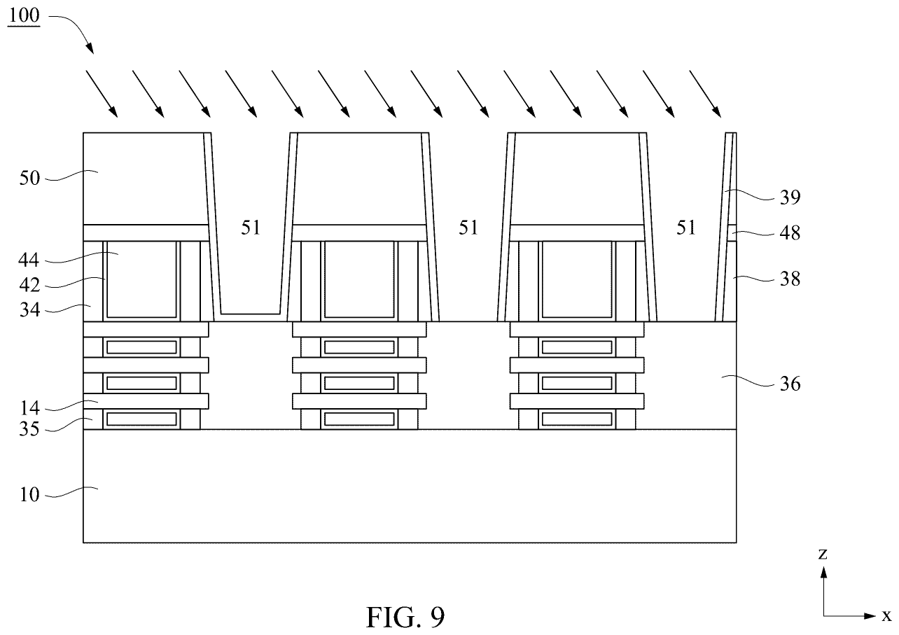

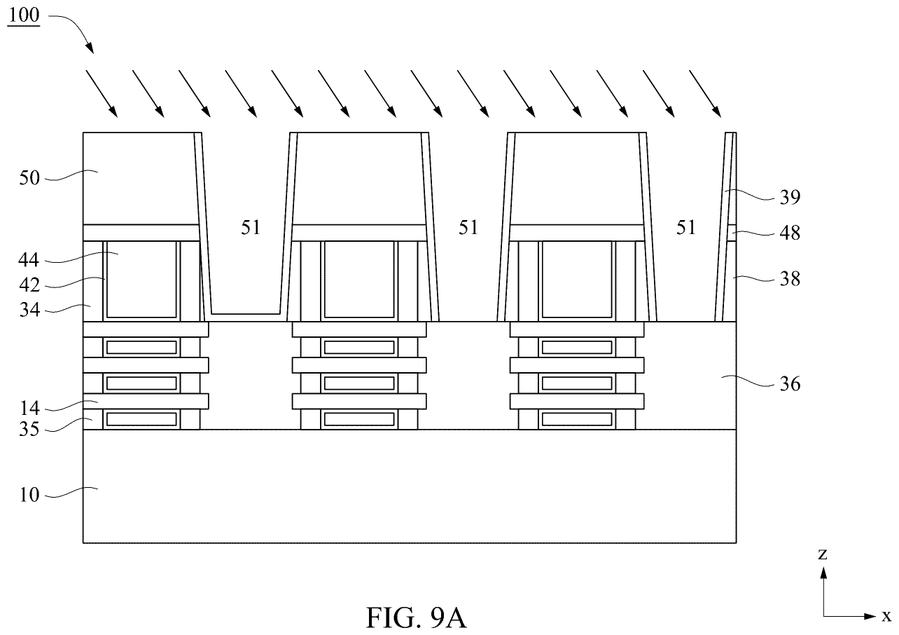

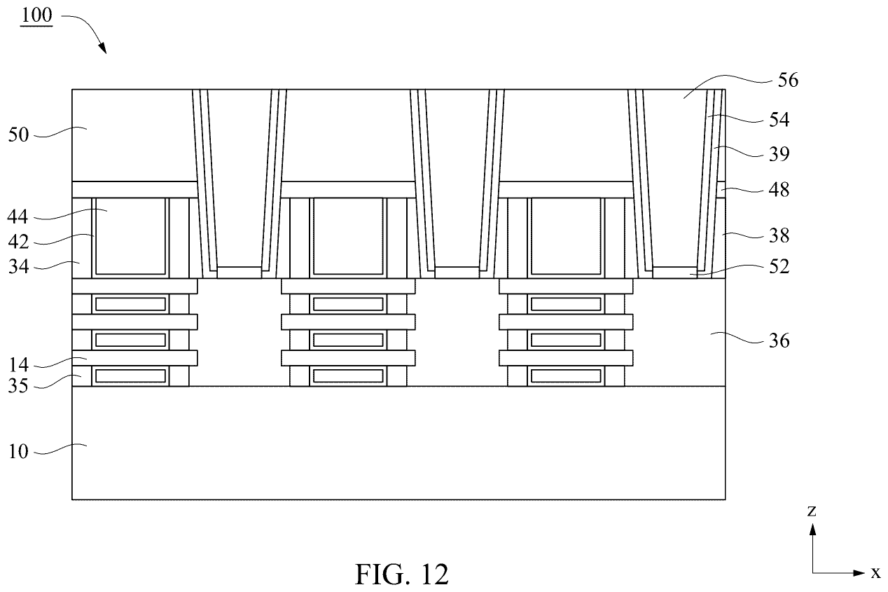

In FIG. 8, contact holes 51 are formed through the ILD layers 40, 48 and 50 and subsequently filled with a conductive material to form the source/drain metal contacts (56, see FIG. 12). Suitable photolithographic and etching techniques are used to form the contact holes 51 through various layers to expose a top surface of the source/drain features 36. In some embodiments, the contact holes 51 may be formed over all source/drain features 36 to form source/drain metal contacts 56 thereon to achieve structure balance. In other embodiments, the contact holes 51 are formed over selected source/drain features 36 to be connected to power supply or signal lines from the top side. In the embodiment as shown in FIG. 8, the remaining CESL 38 may have a thinner upper portion and a thicker lower portion. In some embodiments, the top of the CESL 38 in one or more of the contact holes 51 may be removed to expose he top portion of the sidewall 34 as shown in FIG. 8A. As a consequence, a top portion of the Si spacer 39 to be formed subsequently may be in direct contact with the top corner of the sidewall spacer 34 (see FIG. 9A).

After the formation of the contact holes 51, Si spacers 39 are conformally formed on the sidewalls of the contact holes 51 as shown in FIG. 9. In addition to Si, other materials such as germanium (Ge), silicon germanium (SiGe) or other suitable material that has an etching selectivity higher than the surrounding materials, including the ILD layers 48 and 50, may also be used for forming the spacers 39. The Si spacers 39 may be formed by one or more methods such as PECVD, ALD, and/or other suitable deposition processes. The Si spacers 39 may have a width of about 1 nm to about 3 nm, for about 1 nm to about 5 nm. The depth of the Si spacers 39 may range from about 1 nm to about 60 nm, depending on the depth of the contact holes 51.

In some embodiments, the Si spacers 39 deposited on the sidewall of the contact holes 51 may have a thicker upper portion and a thinner lower portion. Or more specifically, the thickness of the Si spacers 39 may gradually increase towards the bottom of the contact holes 51. As a result, the air gap formed by removal of the Si spacers 39 subsequently may have a gradually decreased thickness.

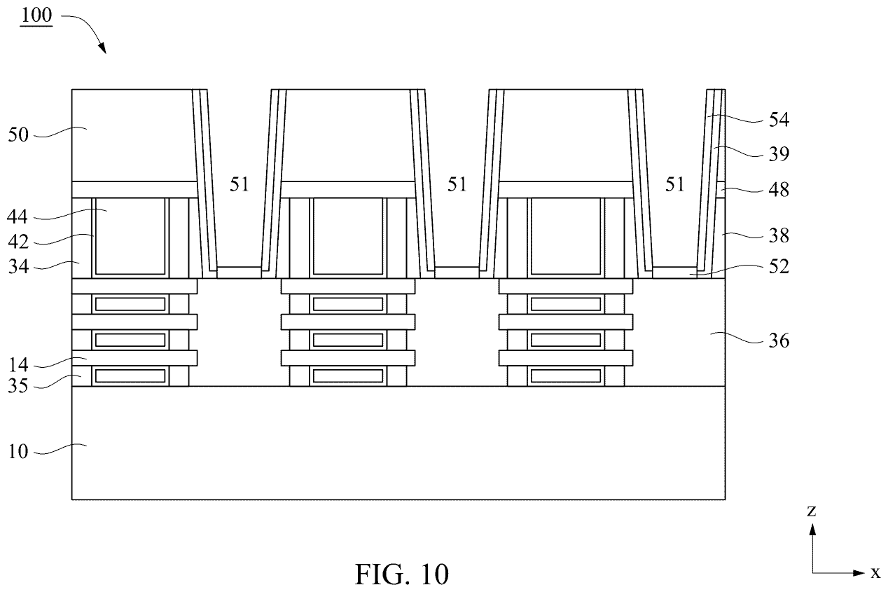

A liner layer 54 is then formed on the surface of the Si spacer 39 as shown in FIG. 10. The liner layer 54 may include a carbon-doped SiN, a high-density SiN, and/or other suitable materials that has a lower etching selectivity in a subsequent etching process for removing the Si spacers 39. The liner layer 54 may be formed by one or more methods such as PECVD, ALD, and/or other suitable deposition processes.

A silicide layer 52 may also be selectively formed over a top surface of the source/drain features 36 exposed by the contact holes 51, as shown in FIG. 10. The silicide layer 52 conductively couples the source/drain features 36 to interconnect structures, for example, the S/D metal contacts subsequently formed in the contact holes 51. The silicide layer 52 may be formed by depositing a metal source layer to cover exposed surfaces including the exposed surfaces of the epitaxial source/drain features 36 and performing a rapid thermal annealing process. In some embodiments, the metal source layer includes a metal layer selected from but not limited Ti, Co, Ni, NiCo, Pt, Ni(Pt), Ir, Pt(Ir), Er, Yb, Pd, Rh, Nb, or TiSiN. After the formation of the metal source layer, a rapid thermal anneal process is performed, for example, a rapid anneal at a temperature between about 700° C. and about 900° C. During the rapid anneal process, the portion of the metal source layer over the source/drain features 36 reacts with silicon in the source/drain features 36 to form the silicide layer 52. Unreacted portion of the metal source layer is then removed. In some embodiments, the silicide layer 52 has a thickness in a range between about 0.5 nm and 10 nm.

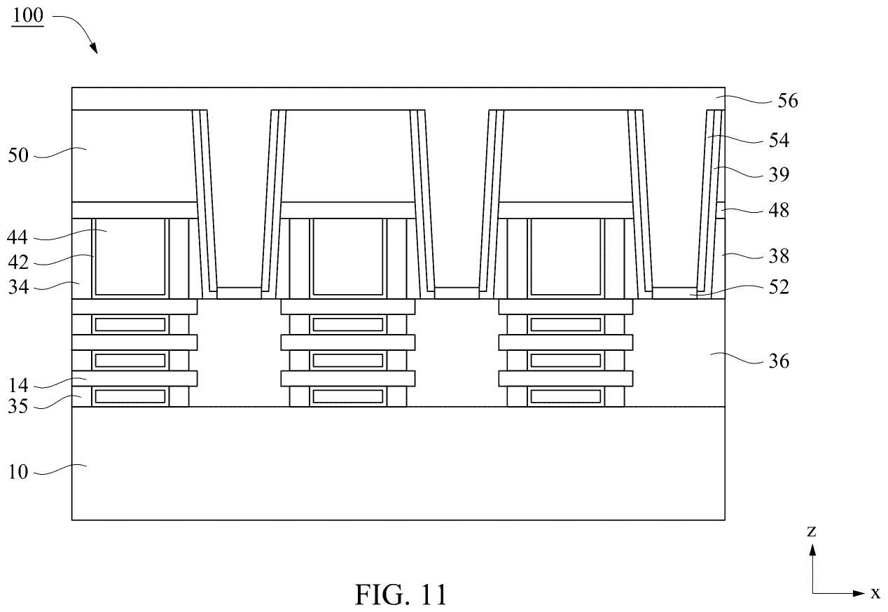

A conductive material 55 (See FIG. 11) is to be formed to fill contact holes 51 and form the source/drain (S/D) metal contacts 56 (see FIG. 12). However, during the process of growing the S/D metal contact 56, the conductive material 55 may grow rapidly on the exposed portion of the Si spacers 39 at the top of the contact holes 51. The rapidly grown conductive material 55 may merge at the top of the contact holes 51 before the lower portion of the contact holes 51 is properly filled with the conductive material 55. Voids may thus be formed within the S/D metal contacts 56, and cause significant metal loss that seriously degrades the device performance. To resolve such an issue, at least the top portion of the Si spacers 39 may be treated to reduce the growth rate of the conductive material 55 thereon.

According to some embodiments, an ion implantation process may be performed to treat the Si spacers 39 before forming the conductive material 55. As shown in FIG. 9, ions 53 are implanted with a tilt angle θ into at least an upper portion of the Si spacers 39. The implantation conditions may be controlled to adjust the depth of the Si spacers 39 to be treated. For example, the treated depth may range from about 1 nm to about 30 nm. When nitrogen is used to perform the ion implantation process, at least an upper portion with a depth from about 1 nm to about 30 nm of the Si spacers 39 is subject to a nitridation process and converted into a nitrogen-containing barrier layer to reduce growth rate of the conductive material 55 thereon. The reduced growth rate of the conductive material 55 on the upper portion of the Si spacers 39 prevents an early merge of the conductive material 55 at the top portion of the contact holes 51. Consequently, the lower portion of the contact holes 51 may be sufficiently filled with the conductive material 55 without significant metal loss. In addition to nitrogen, the ion species such as Ge, Xe, Ar, Si, P, B, or O may also be used for the ion implantation process. According to some embodiments, the ion implantation process may be performed with an implant energy of about 1 keV to about 50 keV, a dosage of nitrogen of about 1E14 atoms/cm² to about 1E19 atoms/cm² and a tilt angle of about 0° to about 90° at a temperature of about −100° C. to about 500° C. Under such conditions, the concentration of the nitrogen introduced into the upper portion may range from about 1E19 atoms/cm³ to about 1E23 atoms/cm³, while a concentration of nitrogen that may be introduced into a lower portion of the Si spacers 39 is controlled lower than about 1E18 atoms/cm³.

After the ion implantation process, the S/D metal contacts 56 are formed to fill the respective contact holes 51. As shown in FIG. 11, the S/D metal contacts 56 may be formed by depositing conductive material into the contact holes 51 and over the top surface of the ILD 50. A suitable deposition process, such as CVD, PVD, plating, ALD, or other suitable techniques may be used for forming the conductive layer material. The conductive material may include but not limited to W, Co, Ru, Ti, Ni, Cu, Au, Ag, Pt, Pd, Ir, Os, Rh, Al, Mo, or the like.

Subsequently, a planarization process, for example, a CMP process, is performed on the conductive material 55 until the ILD 50 is exposed. According to the embodiment as shown in FIG. 12, the S/D metal contacts 56 are formed with a top surface level with a top surface of the ILD 50 after the CMP process.

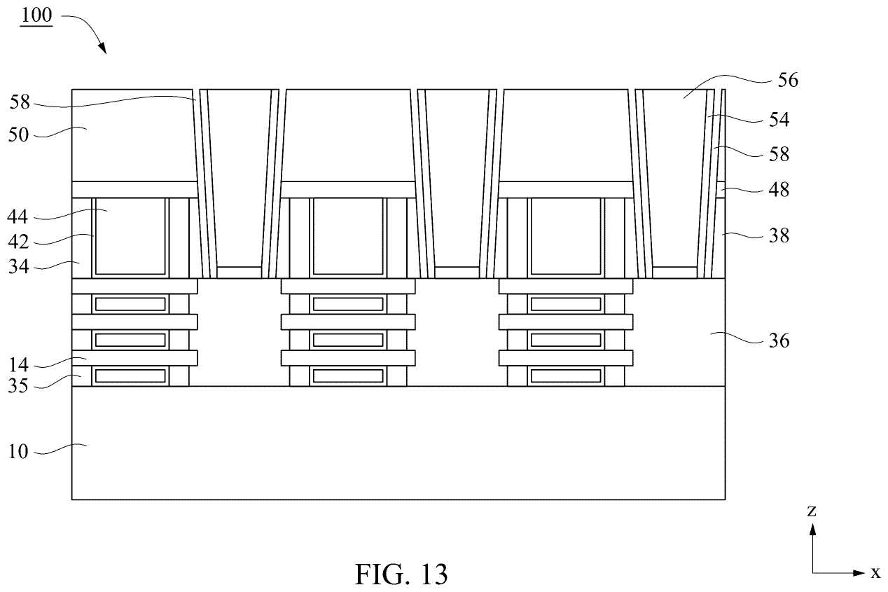

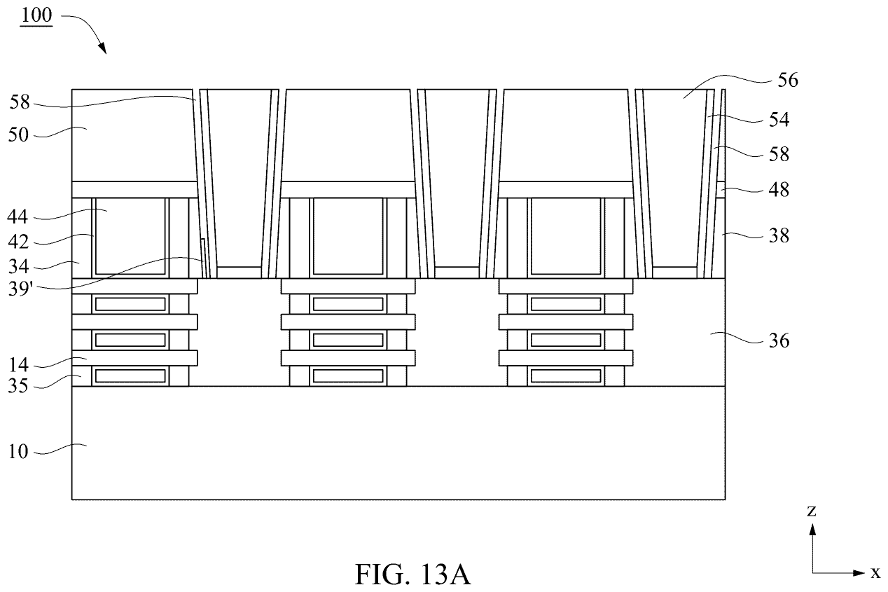

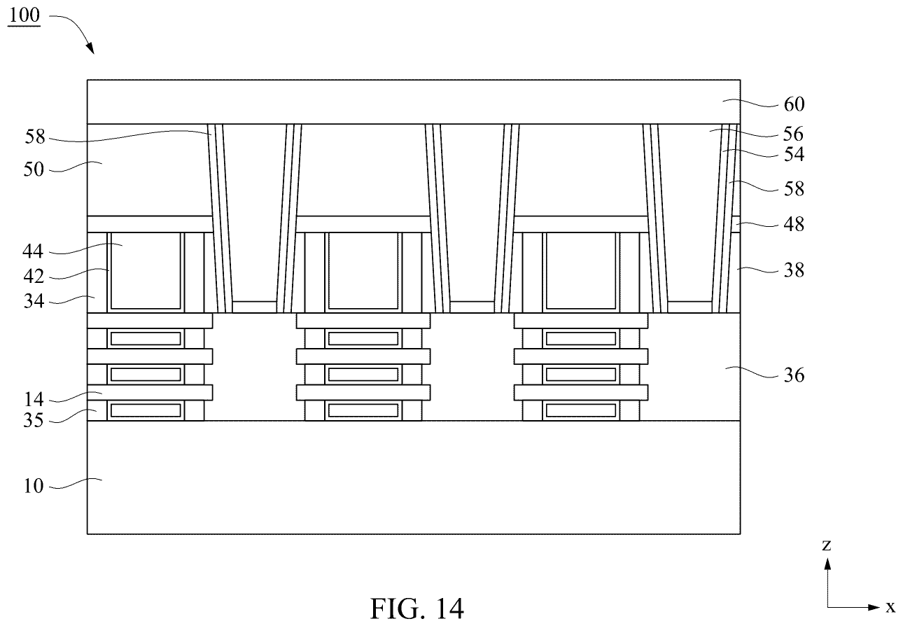

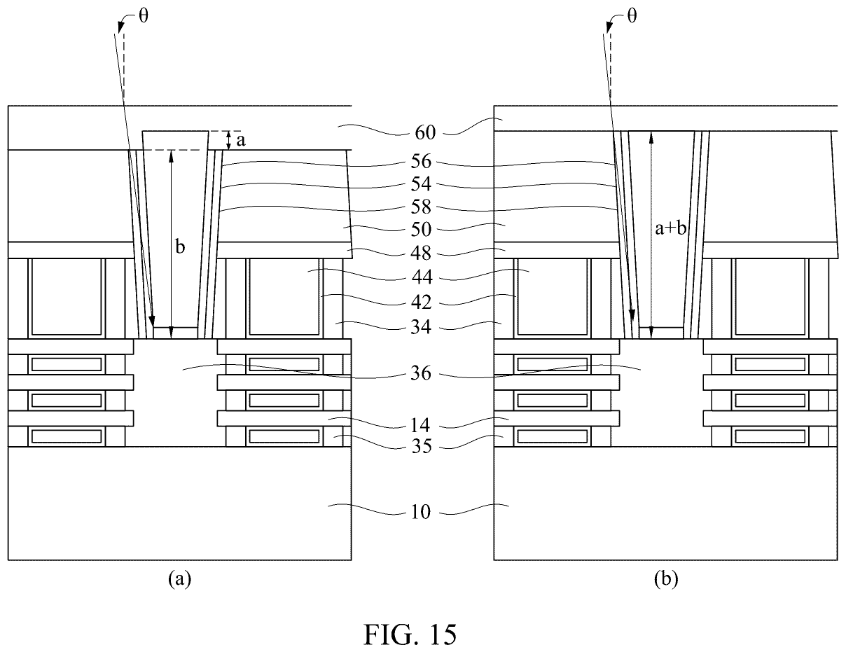

In FIG. 13, the Si spacers 39 are removed to an air gap 58 between each pair of adjacent metal gates 44 and S/D metal contacts. The Si spacers 39 may be removed by an etching process. As previously discussed, the Si spacers 39 is formed from materials having a different etching selectivity from the surrounding structures, including the ILD 50 and the liner layer 54. For example, the Si spacers 39 made of Si or other materials such as Ge, SiGe may be removed by an etching process with a removal rate at least 10 times faster than the materials of the liner layer 54 made of high-density SiN and the material of ILD 50 made of SiO₂. The selective etching process may include dry etching, wet etching, reactive ion etching (RIE), and/or other suitable processes. For example, a dry etching process may be performed using an oxygen-containing gas, a fluorine-containing gas (e.g., CF₄, SF₆, CH₂F₂, CHF₃, and/or C₂F₆), a chlorine-containing gas (e.g., Cl, CHCl₃, CCl₄, and/or BCl₃), a bromine-containing gas (e.g., HBr and/or CHBR₃), an iodine-containing gas, other suitable gases and/or plasmas, and/or combinations thereof. A plasma etching process may also be conducted at a flow rate of about 500 standard cubic centimeters per minute (sccm) to about 2000 sccm. In some other embodiments, a wet etching process using etching in diluted hydrofluoric acid (DHF); potassium hydroxide (KOH) solution; ammonia; a solution containing hydrofluoric acid (HF), nitric acid (HNO₃), and/or acetic acid (CH₃COOH); or other suitable wet etchant may be performed. The wet etching process may be conducted in any suitable manner such as by immersing semiconductor device structure 100 into the wet etchant for a time period (e.g., less than 1 hour).

As the Si spacers 39 have a width of about 1 nm to about 3 nm along the x-direction, or alternatively, 1 nm to about 5 nm the air gaps 58 resulting from removal of the Si spacers 39 have a thickness of about 1 nm to about 3 nm or about 1 nm to about 5 nm. In some embodiments, a portion of the Si spacer 39′ may remain on a bottom portion of the sidewall spacer 34 after the etching process for forming the air gaps 58 as shown in FIG. 13A.

According to the embodiments as shown in FIGS. 8A and 9A, as the top of the CESL 38 in some of the contact holes 51 may be etched to expose the top corner of the sidewall spacer 34, the top portion of the air gap 58 may be formed directly adjacent to the top portion of the sidewall spacer 34 as shown in FIG. 13A.

After the formation of the air gaps 58, an ILD 60 is formed to cover the ILD 50, the air gaps 58, and the S/D metal contacts 56 as shown in FIG. 14. The ILD 60 may be formed by a suitable deposition process, such as CVD, PVD, or ALD. The ILD 60 may be a dielectric layer including but not limited to tetraethyl orthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), SiN, and/or other suitable dielectric materials. As the air gaps 58 are formed with very small width, there is no risk of the ILD 60 to penetrate deeply into the air gaps 58.

As it will be discussed later, contact structures may be formed to provide electric connection for the metal gates 44 and the S/D features 36. For example, vias or contact plugs (VG) may be formed to extend through the ILD 50 to connect with the metal gates 44, and vias or contact plugs (VD) may be formed to extend through the ILD 60 to connect with the S/D metal contacts 56. During formation of the VD, conductive material may leak into the air gaps 58 and diffuse through the ILD 50 towards VG to result in short between the adjacent S/D metal contacts 56 and metal gates 44. To resolve the leakage problem, the air gaps 58 may be sealed by forming a low-k material prior to formation of the contact structures. However, the sealing capability and uniformity of the low-k sealing material are often unsatisfactory.

Therefore, ion implantation that may induce dielectric expansion of the ILD 50 across the air gaps 58 is introduced to prevent leakage of conductive materials during subsequent processes for forming conductive structures. However, during the ion implantation process, ions implanted into the air gaps 58 may damage the S/D features 36 and even the channel regions 14 to degrade the device performance. The amount of implanted ions reaching and impinging on the S/D features 36 through the air gaps 58 may damage the S/D features or even the adjacent channel regions 14.

In some situations, the material of the ILD 50 has a faster removal rate than that of the conductive material 55 during the CMP process for polishing the conductive material 55 for forming the S/D metal contacts 56. As a result, the top surface of the ILD 50 is polished with a top surface lower than a top surface of the S/D metal contacts 56. For example, the ILD 50 may be recessed from the S/D metal contacts 56 by a height of “a” as shown in FIG. 15(a). In this case, the height of air gaps 58 through which ions may pass is “b.” As shown in FIG. 15(b), by controlling the removal rates of the ILD 50 and the conductive material 55, the ILD 50 may be polished with a top surface level with the top surface of the S/D metal contact 56 after the CMP process. In the embodiment as shown in FIG. 15(b), the height of the air gaps 58 through which ions may pass increases from “b” to “a+b”. When ions are implanted into the air gaps 58 with a tilt angle θ, the shorter path “b” in FIG. 15(a) allows the ions to reach the bottom of the air gap 58 to impinge on the surface of the S/D features 36 or even the channel regions 14. In contrast, with a longer height “a+b” as shown in FIG. 15(b), the ions may impinge on the liner layer 54 before reaching the surface of the S/D region 36. The number of the ions to reach the surface of the S/D features 36 is thus reduced to lessen the damage of the S/D features 36 and the channel regions 14 caused by a subsequently performed ion implantation process.

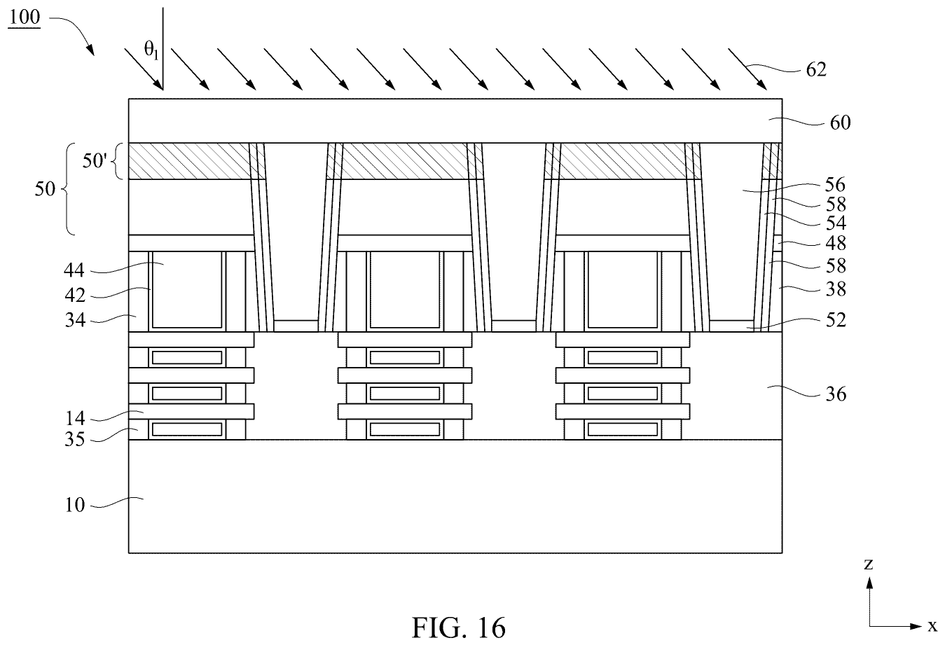

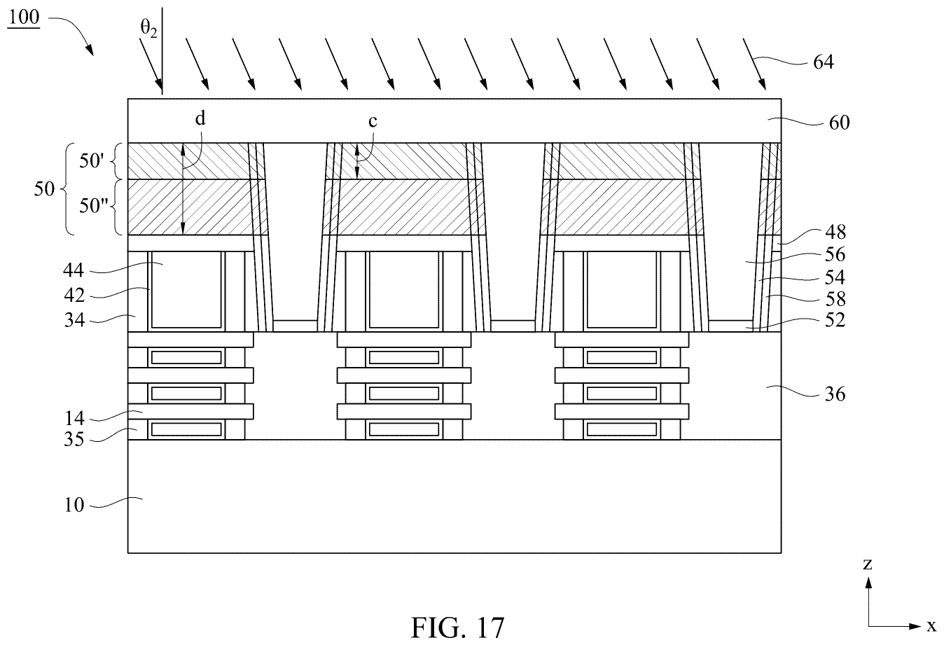

FIGS. 16 and 17 show an embodiment employing a two-step ion implantation process for sealing the air gaps 58 to further suppress penetration of implanted ions into the S/D features 36, and thus to minimize damages of the S/D features 36 and the channels 14. In some embodiments, more than two steps of ion implantation may also be adapted. In FIG. 16, a first step of ion implantation is performed on the ILD 60 and of the ILD 50. The implanted depth or thickness of the ILD 50 may be adjusted by controlling the implantation conditions such as the implantation energy. For example, an upper portion 50′ with a thickness or depth “c” of the implanted region 50′ that may be implanted with ions may range from about 1 nm to about 15 nm by controlling implantation energy from about 1 keV to about 10 keV and an ion dosage from about 1E14 atoms/cm² to about 1E16 atoms/cm² at about −100° C. to about 500° C. The ions 62 may be implanted into the ILD 60 and ILD 50 with a tilt angle θ₁ of about 45° to about 60°. Under such implantation conditions, the dopant concentration of the implanted region 50′ of the ILD 50 is about 1E18 atoms/cm³ to about 1E23 atoms/cm³. Nitrogen may be used in the first step of ion implantation. Other species such as Ge, Xe, Ar, Si, P, B, or O may also be used in the first step of ion implantation process. The first step of ion implantation causes the material of the ILD 50 in the implanted region 50′ to expand across the air gaps 58 to partially seal the air gaps 58. As shown in FIG. 16, the portion with a thickness or depth of “c” of the air gaps 58 has been sealed by the ILD 50 expanded by the first step of ion implantation.

The first step of ion implantation is controlled to seal a shallow region of the air gaps 58 with a relatively large tilt angle, ions penetration into a deeper region of the air gaps 58 can be efficiently suppressed. However, the sealed portion of the air gaps 58 is too thin to efficiently prevent conductive material from penetrating through during formation of the conductive structures such as VD subsequently. Therefore, according to some embodiments, a second step of ion implantation is introduced increase the thickness of the sealed portion of the air gaps 58 to further suppress the penetration of conductive material into the unsealed portion of the air gaps 58. As shown in FIG. 17, the sealed portion may extend from the “c” to “d” by the second step of ion implantation depth. In some embodiments, the thickness “d” may be approximately the same as the thickness of the ILD 50. As the thickness of the ILD 50 is about 1 to about 60 nm, the thickness “d” of the sealed portion of the air gaps 58 may extend as deep as to about 60 nm. The ratio of “c/d” may range from about ¼ to about ½ according to some embodiment.

In some embodiments, the second step of ion implantation may be conducted with an implantation energy of about 15 keV to about 20 keV and a nitrogen dosage of about 1E14 atoms/cm³ to about 1E16 atoms/cm³ at a temperature of about −100° C. to about 500° C. The formation of the sealed portion at the upper portion of the air gaps 58 effectively reduces penetration of ions into the S/D features 56 during the second step of ion implantation. Therefore, the ions 64 may be implanted with a tilt angle θ₂ smaller than the tilt angle θ₁ used in the first step of ion implantation. For example, the tilt angle θ₂ may range from about 15° to about 20°. Under such implantation conditions, the portion of the air gaps 58 sealed by the second step of ion implantation may have a dopant concentration of about 1E18 atoms/cm² to about 1E23 atoms/cm². Nitrogen may be used in the second step of ion implantation, while other species such as Ge, Xe, Ar, Si, P, B, or O may also be used in the second step of ion implantation. According to some embodiments, the dopant concentration of the sealed portion 50′ is higher than that of the sealed portion 50.”

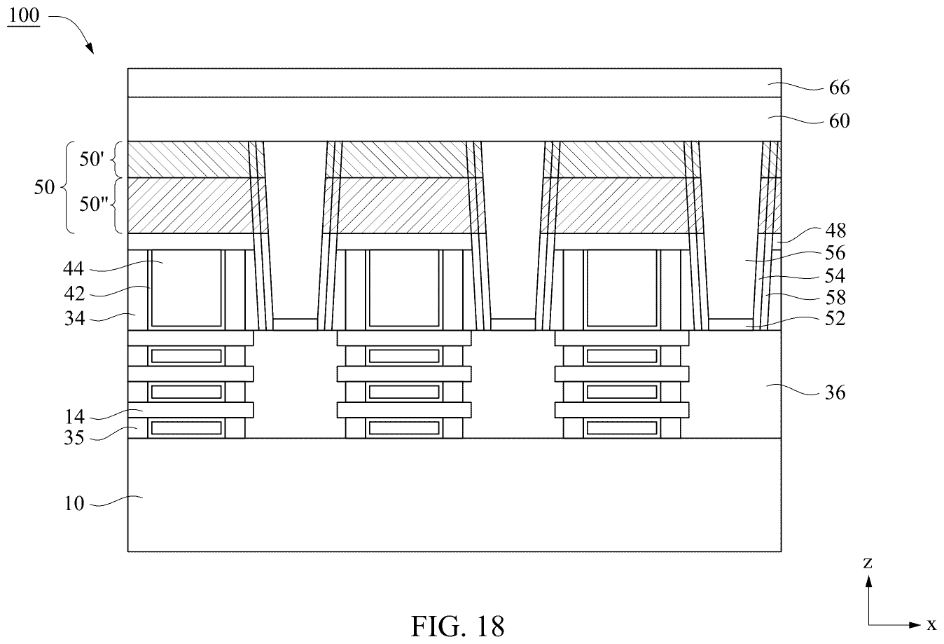

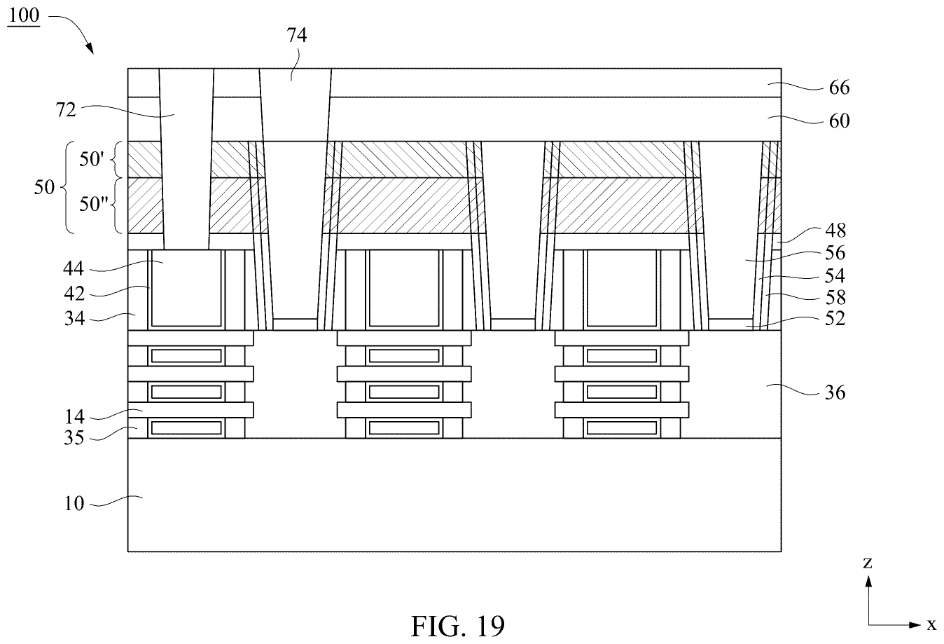

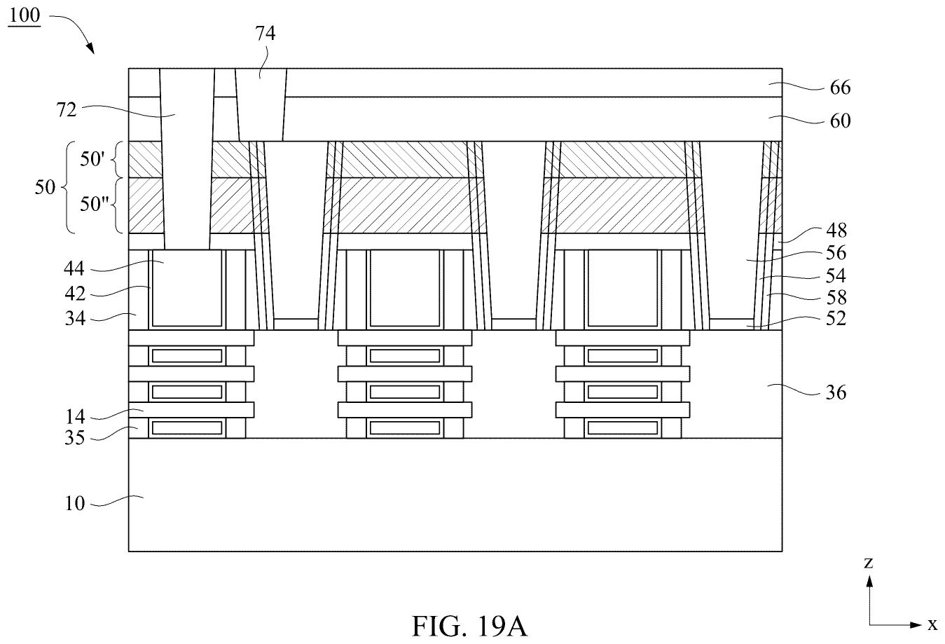

After the multi-step of ion implantation process, a dielectric layer 66 is formed on the ILD 60 as shown in FIG. 18. The dielectric layer 66 may be an ILD made of materials comprising Si, O, C, and/or H such as SiO₂, SiCOH, and SiOC. Organic material such as polymers may also be used to form the ILD 66.

In FIG. 19, conductive structures including the contacts (VD) 74 for contacting the S/D metal contacts 56 and the contacts (VG) 72 for contacting the metal gate are formed. The VD 74 may be formed by patterning the ILD 66 and the ILD 60 with openings exposing the S/D metal contacts 56, followed by filling the openings with conductive material such as W, Co, Ru, Ti, Ni, Cu, Au, Ag, Pt, Pd, Ir, Os, Rh, Al, Mo, or the like by a suitable process such as CVD, PVD, plating, or ALD. The VG 72 may be formed by patterning the ILD 66, the ILD 60, and ILD 50 with openings that expose the metal gates 44 and then filling the openings with conductive material such as W, Co, Ru, Ti, Ni, Cu, Au, Ag, Pt, Pd, Ir, Os, Rh, Al, Mo, or the like by a suitable process such as CVD, PVD, plating, or ALD. As shown in FIG. 19, the air gaps 58 remain unsealed at the portion extending between the adjacent metal gates 44 and the S/D metal contacts 56, such that the parasitic capacitance is effectively reduced, while the S/D features 36 and the channels 14 are protected by the sealed portion from being damaged by ions implanted during various steps of ion implantation process. FIG. 19 shows the VD 74 is formed with a well-controlled overlay (OVL). When the OVL is not properly controlled, the VD 74 may shift to misalign with the S/D metal contact 56 as shown in FIG. 19A. The sealed portions 50′ and 50″ may play an even more important role in preventing the leakage that is more likely to occur since portion of the VD 74 is directly over the air gap 58.

FIG. 20 shows a method 100 for manufacturing a semiconductor device structure 100 with air gaps to minimize parasitic capacitance Ceff between adjacent conductive structures, such as adjacent metal gates and metal layers over diffusion layers (MD), for example, S/D metal contacts. The method 100 adapts a multi-step ion implantation process to seal the air gaps to minimize damages of the S/D features and the channel regions. The method 100 further includes an additional ion implantation process prior to formation of the S/D metal contacts to avoid metal loss thereof.

The method begins at operation 102 in which a plurality stacks of channel regions 14 and S/D features 36 interposed in a substrate 10, and a metal gate 44 formed on each of the stacks of nanosheets 14. The semiconductor device structure manufactured by operation 102 can be referred to the semiconductor device structure 100 as shown in FIGS. 1-5. At operation 104, with reference to FIGS. 6 and 7, an ILD 50 is formed over the metal gates 44. As shown in FIG. 8, contact holes 51 are formed to expose the S/D features 36 at operation 106. At operation 108, Si spacers 39 are formed conformally on sidewalls of the contact holes, and liner layers 54 are formed on the Si spacers 39 as shown in FIG. 9. At operation 110, an ion implantation process is performed to treat the Si spacers 39. The Si spacers 39 may be treated by implanting nitrogen thereon. At least a portion of the Si spacers 39 is thus subject to a nitridation process and converted into a barrier layer. During formation of the S/D metal contacts 56 as shown in FIG. 12, the growth rate of the conductive materials 55 used to form the S/D metal contacts 56 is reduced to prevent merge of the conductive material 55 at the top portion of the contact holes 51 before the lower portion of the contact holes 51 are properly filled with the conductive material 55. Thereby, metal loss of the S/D metal contacts is prevented. According to some embodiments of this disclosure, the S/D metal contacts 56 have a top surface level with a top surface of the ILD 50.

At operation 114 and in FIG. 13, the Si spacers 39 are removed to form the air gaps 58 between the S/D metal features 56 and the metal gates 44. At operation 116 and FIG. 14, an ILD 60 is formed on the semiconductor device structure 100. At operations 118 and 120 with reference to FIGS. 16 and 17, a two-step ion implantation process is performed. As discussed at operation 112, the top surface of the ILD 50 is at the same level as the top surface of the S/D metal contacts 56. This may reduce an amount of implanted ions to reach the bottom of the contact holes 51 to damage on the S/D features 36. The damage of S/D features 36 and even the channel regions 14 caused by the multi-step ion implantation process can thus be suppressed. In the first step of ion implantation at operation 118, ions are implanted with a large tilt angle and low implantation energy to control dielectric expansion of the ILD 50 across the air gaps 58 within a shallow top region. The large tilt angle and shallow implantation depth prevent the ions from being implanted towards a deep level of the air gaps 58. Operation 118 thus creates a shallow sealed portion at the top portion of the air gaps 58 to retard penetration of ions into a deep level of the air gaps 58, for example, the portion of the air gaps 58 at the same levels of the metal gates 44 and immediately above the S/D features 36. The second step of ion implantation may then be performed with a higher implantation energy and smaller tilt angle at operation 120 as ion penetration towards the deep level is retarded by the shallow sealed portion at the top of the air gaps 58. The second step of ion implantation causes a deeper region of the ILD 50 to expand across the air gaps 58, such that the sealed portion of the air gaps 58 is thickened. At operation 122, an ILD 66 may be formed and through which conductive structures VD (74 in FIG. 19) is formed to provide electric connection to the S/D metal contacts. Conductive structures VG that provides electric connection to the metal gates 44 are also formed to extend through the ILD 66, 60, and 50 at operation 122. As the top portion of the air gaps 58 is sealed with a sufficient depth or thickness, penetration of the material of the VD 74 is properly blocked. Short between the metal gates 44 and the S/D metal contacts 56 caused by leak of the conductive materials by formation of VD 74 is thus avoided.

According to one embodiment of the present disclosure, a semiconductor device is provided. The semiconductor device comprises a channel region and a source/drain (S/D) region formed adjacent to the channel region in a substrate, a metal gate on the channel region and an interlayer dielectric layer (ILD) over the metal gate. An S/D metal contact is formed on the S/D region adjacent to the metal gate and spaced from the metal gates and the ILD by an air gap structure. The air gap structure includes a sealed portion extending from a top surface to a bottom surface level of the ILD and an unsealed portion extending from the bottom surface level of the ILD to a top surface level of the S/D region. The ILD has a depth of about 1 nm to about 30 nm, such that the sealed portion of the air gap has a depth of about 1 nm to about 30 nm. The air gap structure has a width of about 1 nm to about 3 nm; or about 1 nm to about 5 nm.

In another embodiment of the present disclosure, a method is provided. The method includes forming a channel region in a substrate, a source/drain (S/D) feature adjacent to the channel region in the substrate, a metal gate on the channel region, an interlayer dielectric layer (ILD) on the metal gate, and a S/D metal contact over the S/D feature. The S/D metal contact extends from a bottom surface level of the metal gate to a top surface level of the ILD. An air gap structure is formed to surround the S/D metal contact and to isolate the S/D metal contact from the metal gates and the first ILD. The method seals a first portion of the air gap by performing a first ion implantation process with a first implantation energy and a first implantation angle and a second portion of the air gap by performing a second ion implantation process with a second implantation energy and a second implantation angle. The first implantation energy is lower than the second implantation energy, and the first implantation angle is larger than the second implantation angle.

In yet another embodiment of the present disclosure, a method of sealing an air gap formed between an S/D metal contact and a metal gate is provided. The air gap extends from a bottom surface level of S/D metal contact to a top surface level of an ILD formed on the metal gate. The method comprises performing a first ion implantation to seal a first portion of the air gap by dielectric expansion of the ILD and a second ion implantation to seal a second portion of the air gap by dielectric expansion of the ILD, the second portion being deeper than the first portion. Ions are implanted with a first tilt angle in the first ion implantation process larger than a second tilt tile angle in the second ion implantation process. The method also includes forming a spacer on a sidewall of a contact hole to be filled with the S/D metal contact is to be formed, treating at least a portion of the spacer with ion implantation, selectively removing the treated spacer after the S/D metal contact is formed.

It will be understood that not all advantages have been necessarily discussed herein, no particular advantage is required for all embodiments or examples, and other embodiments or examples may offer different advantages.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a channel region and a source/drain (S/D) region adjacent to the channel regions in a substrate;
a metal gate on the channel region and a first interlayer dielectric layer (ILD) over the metal gate; and
an S/D metal contact on the S/D region and adjacent to the metal gate and the first ILD;
an air gap structure disposed between the S/D metal contact and the metal gate and the first ILD, wherein the air gap structure includes:
a sealed portion extending from a top surface to a bottom surface level of the first ILD; and
an unsealed portion extending from a bottom surface level of the ILD to a top surface level of S/D region.

2. The semiconductor device of claim 1, wherein the S/D metal contact has a top surface level with the top surface of the first ILD.

3. The semiconductor device of claim 1, wherein the air gap has a variable thickness.

4. The semiconductor device of claim 3, wherein the sealed portion of the air gap structure is filled with material of the first ILD by dielectric expansion.

5. The semiconductor device of claim 3, wherein the sealed portion of the air gap structure has a depth of about 1 nm to about 30 nm.

1. emiconductor device of claim 1, wherein the air gap structure has a width of about 1 nm to about 5 nm.

7. The semiconductor device of claim 1, wherein the sealed portion include a first ion implanted layer and a second ion implanted layer, and a depth ratio of the first ion implanted layer to the second ion implanted layer is about ¼ to about ½.

8. The semiconductor device of claim 1, wherein the sealed portion of the air gap structure has a concentration of dopants of about 1E18 atoms/cm³ to about 1E23atoms/cm³ from an ion implantation process.

9. The semiconductor device of claim 1, wherein the air gap is formed in direct contact a top corner of a sidewall spacer formed on a side of the metal gate.

10. A method, comprises:
forming a channel region in a substrate;
forming a source/drain (S/D) feature adjacent the channel regions in the substrate;
forming a metal gate on the channel region;
forming a first interlayer dielectric layer (ILD) on each of the metal gate;
forming a S/D metal contact over the S/D feature, the S/D metal contact extending from a bottom surface level of the metal gate to a top surface level of the ILD;
forming an air gap surrounding the S/D metal contact to isolate the S/D metal contact from the metal gates and the first ILD;
sealing a first portion of the air gap by performing a first ion implantation process with a first implantation energy and a first implantation angle; and
sealing a second portion of the air gap by performing a second ion implantation process with a second implantation energy and a second implantation angle, wherein the first implantation energy is different from the second implantation energy, and the first implantation angle is different from the second implantation angle.

11. The semiconductor device of claim 10, further comprising:
forming a contact hole to expose the S/D feature;
forming a spacer on a sidewall of the contact hole;
treating the spacer with ion implantation before forming the S/D metal contact;
filling the contact hole with conductive material to form the S/D metal contact; and
selectively removing the spacer to form the air gap.

12. The method of claim 11, further comprising performing an ion implantation on the spacer before forming the S/D metal contact.

13. The method of claim 11, further comprising performing ion implantation with an implantation energy of about 1 keV to about 50 keV at and an implantation angle of about 0° to about 90° at −100° C. to about 500° C.

14. The method of claim 11, wherein the ion implantation is performed with an ion dosage of about 1E14 atoms/cm² to about 1E16 atoms/cm².

15. The method of claim 14, wherein the spacer includes a first portion with a dopant concentration of about 1E19 atoms/cm³ to about 1E23 atoms/cm³ and a second portion with a dopant concentration lower than about 1E18 atoms/cm³ after being treated by ion implantation.

16. The method of claim 10, wherein the first implantation energy is about 10 keV and the second implantation energy is about 15 keV to about 20 keV.

17. The method of claim 10, wherein the first implantation angle is about 45° and the second implantation angle is about 15° to about 45°.

18. The method of claim 10, wherein the sealed portion of the air gap has a dopant concentration of about 1E19 atoms/cm³ to about 1E23 atoms/cm³.

19. A method of sealing an air gap formed between a S/D metal contact and a metal gate, the air gap extending from a bottom surface level of the metal gate to a top surface level of an ILD formed on the metal gate, the method comprising:
performing a first ion implantation to seal a first portion of the air gap by dielectric expansion of the ILD;
performing a second ion implantation to seal a second portion of the air gap by dielectric expansion of the ILD, the second portion being deeper than the first portion, wherein
ions are implanted with a first tilt angle in the first ion implantation process different from a second tile angle in the second ion implantation process.

20. The method of claim 19, further comprising:
forming a spacer on a sidewall of a contact hole to be filled with the S/D metal contact is to be formed;
treating at least a portion of the spacer with ion implantation; and
selectively removing the treated spacer after the S/D metal contact is formed.
